(19) United States
(12) Patent Application Publication
(10) Pub. No.: US 2026/0129849 A1
(43) Pub. Date: May 7, 2026

(54) ELECTRONIC FUSE STORAGE UNIT AND STORAGE ARRAY

(71) Applicant: Shanghai Huali Integrated Circuit Corporation, Shanghai (CN)

(72) Inventors: Yinxiang WANG, Shanghai (CN); Ying YAN, Shanghai (CN)

(73) Assignee: Shanghai Huali Integrated Circuit Corporation, Shanghai (CN)

(21) Appl. No.: 19/220,976

(22) Filed: May 28, 2025

(30) Foreign Application Priority Data
Nov. 7, 2024 (CN) 202411589354.4

(51) Int. Cl. H10B 20/25; G11C 17/16; H01L 23/525

(52) U.S. Cl. CPC H10B 20/25; G11C 17/16; H10W 20/493

(57) ABSTRACT

The present application discloses an electronic fuse storage unit and a storage array thereof, the electronic fuse storage unit has a control transistor and a fuse that are formed in a same active area, an elongated-shape polycrystalline silicon fuse thereof is located at a side of an MOS control transistor and has an end shorted to an end of a drain-side heavily doped region of a nearest MOS control transistor, the area of the electronic fuse storage unit is significantly reduced and it is facilitated to directly perform a combination layout by forming storage unit pairs in a center-symmetric manner to form a storage unit array, and thus, a layout area of a storage array can be reduced to obviously increase the layout efficiency for composing the storage array by the electronic fuse storage unit.

### CROSS-REFERENCE TO RELATED APPLICATIONS

This application claims priority to Chinese patent application No. 202411589354.4, filed on Nov. 7, 2024, the disclosure of which is incorporated herein by reference in its entirety.

### TECHNICAL FIELD

The present application relates to semiconductor manufacturing technology, and in particular to an electronic fuse (efuse) storage unit and a storage array.

### BACKGROUND

An eFuse storage unit has a structure generally composed by one fuse and one MOS control transistor. It achieves a highly reliable on-chip programming function by fusing the fuse based on the electromigration (EM) principle.

An efuse memory has an area size as one of main design parameters. In a conventional efuse memory layout, an eFuse storage unit array area is formed by combining eFuse storage units, that is, being formed by assembling individual eFuse storage unit layouts, and the storage unit array area accounts for most of an overall area of a memory chip, the area of the eFuse memory chip being mainly determined by an array composed by eFuse storage units, wherein an area of an MOS control transistor accounts for most of an area of a whole efuse storage unit, and the MOS control transistor is a core factor to determine an overall area of an eFuse storage unit. One of effective ways to reduce the area of the memory chip is to improve the layout of the efuse storage unit.

Referring to FIG. 1, it is a dimension of a layout of an existing efuse storage unit for which a metal fuse is employed. The efuse storage unit, for which a 28 nm high-K (HK) process is employed, has an area of 14.4 um2, and an eFuse unit structure includes a MOS control transistor 103 and a fuse 104. The MOS control transistor 103, for which NMOS is usually employed, is located in an NMOS region. The fuse 104 is located in a fuse region. In FIG. 1, the dashed line in the fuse region illustrates the structure of the fuse 104, the fuse 104 consisting of a PAD formed by two metal layers and a metal wire connected between two PADs. By applying a voltage between two PADs when programming, the fusing of the metal wire is realized by EM. In the existing efuse storage unit structure shown in FIG. 2, the area of the MOS control transistor 103 accounts for most of the entire area of the storage unit, and is the major area in the efuse storage unit layout, and the MOS control transistor 103 is a major factor in determining the overall area of the efuse memory.

### BRIEF SUMMARY

The present application is to solve the technical problem of reducing a layout area of a storage array, enabling easy manufacturing and convenient quality controlling, and uniform controllable electronic migration during programming and high reliability after programming is completed.

To solve the above technical problem, the present application provides an electronic fuse storage unit including a control transistor 1 consisting of MOS transistors, and a fuse 2;

the control transistor 1 and fuse 2 are formed in a same active area;

the fuse 2 is an elongated-shape polycrystalline silicon fuse, and located at an A side of the control transistor 1, A being left or right;

length directions of source-side heavily doped regions 207, and drain-side heavily doped regions 208 of respective MOS transistors of the control transistor 1, and the fuse 2 are all a front-to-rear direction;

front ends and rear ends of the source-side heavily doped regions 207, and the drain-side heavily doped regions 208 of the respective MOS transistors are aligned, respectively;

tops of the source-side heavily doped regions 207 of the respective MOS transistors are shorted to a source metal S formed on a first metal layer S by a contact hole 205;

tops of the drain-side heavily doped regions 208 of the respective MOS transistors are shorted to a drain metal D formed on a second metal layer M2 by the contact holes 205;

gate structures 206 of the respective MOS transistors are shorted to a word line metal W formed on the second metal layer M2 by the contact holes 205; and the fuse 2 has an end shorted to a front end or a rear end of a drain-side heavily doped region 208 of an MOS transistor closest to the A side that constitutes the control transistor 1, and the other end located at an A side of a middle portion in a front-to-rear direction of MOS transistor closest to the A side that constitutes the control transistor 1, and shorted to a bit line metal formed at a third metal layer M3 by the contact holes 205.

In some embodiments, the front end or a rear end of the drain-side heavily doped region 208 of the MOS transistor closest to the A side that constitutes the control transistor 1 protrudes towards the A side, forming an L-shape; and an A side of the fuse 2 is aligned with an A side of a protruding portion of the front end or rear end of the drain-side heavily doped region 208 of the MOS transistor closest to the A side that constitutes the control transistor 1.

In some embodiments, the source-side heavily doped regions 207, and the drain-side heavily doped regions 208 of the respective MOS transistors are formed in a self-aligned mode in active areas of both left and right sides of gate structures 206 of the respective MOS transistors; and

the source-side heavily doped regions 207, the drain-side heavily doped regions 208, and the gate structures 206 of the respective MOS transistors are also in an elongated shape in a front-to-rear direction.

In some embodiments, the gate structures 206 comprise gate dielectric layers and gate polysilicon layers stacked in sequence; and for the material of the gate dielectric layers, a high-dielectric-constant material or is silicon dioxide is employed.

In some embodiments, the control transistor 1 is formed by connecting N MOS transistors in parallel, N being an integer greater than 1;

the gate structures 206 of the respective MOS transistors are arranged in an elongated shape in a front-to-rear direction; and

a source-side heavily doped region 207 or a drain-side heavily doped region 208 located between two gate structures 206 is shared by two MOS transistor units adjacent from left to right.

In some embodiments, N is 2, 3, 4 or 5.

In some embodiments, the MOS transistor is an NMOS transistor.

To solve the above technical problem, the present application also provides an electronic fuse storage array composed by the electronic fuse storage units, the electronic fuse storage array comprises a plurality of storage unit pairs 4;

each storage unit pair 4 comprises a left electronic fuse storage unit 41 and a right electronic fuse storage unit 42;

a fuse 2 of the left electronic fuse storage unit 41 is located on the left of the control transistor 1, and the fuse 2 has an end shorted to a front end of a drain-side heavily doped region 208 of a leftmost MOS transistor that constitutes the control transistor 1, and the other end located on the left of a middle portion in a front-to-rear direction of the drain-side heavily doped region 208 of the leftmost MOS transistor that constitutes the control transistor 1;

a fuse 2 of the right fuse storage unit 42 is located on the right of the control transistor 1, the fuse 2 has an end shorted to a rear end of a drain-side heavily doped region 208 of a rightmost MOS transistor that constitutes the control transistor 1, and the other end located on the right of a middle portion in a front-to-rear direction of the drain-side heavily doped region 208 of the rightmost MOS transistor that constitutes the control transistor 1; and

the fuse 2 of the left electronic fuse storage unit 41 and the fuse 2 of the right electronic fuse storage unit 42 are connected into a whole in a front-to-rear direction.

In some embodiments, a middle connection area of fuses 2 of both left and right electronic fuse storage units in the storage unit pair are shorted to a bit line metal BL formed on a third metal layer M3 by corresponding contact holes 205;

respective gate structures 206 of the left electronic fuse storage unit are shorted to a first word line metal W1 formed on a second metal layer M2 by corresponding contact holes 205;

respective gate structures 206 of the right electronic fuse storage unit are shorted to a second word line metal W2 formed on the second metal layer M2 by corresponding contact holes 205;

tops of drain-side heavily doped regions 208 of respective MOS transistors of the left electronic fuse storage unit are shorted to a first drain metal D1 formed on the second metal layer M2 by contact holes 205;

tops of drain-side heavily doped regions 208 of respective MOS transistors of the right electronic fuse storage unit are shorted to a second drain metal D2 formed on the second metal layer M2 by contact holes 205;

tops of source-side heavily doped regions 207 of respective MOS transistors of the left electronic fuse storage unit are shorted to a first source metal S1 formed on the first metal layer M1 by contact holes 205; and

tops of source-side heavily doped regions 207 of respective MOS transistors of the right electronic fuse storage unit are shorted to a second source metal S2 formed on the first metal layer M1 by contact holes 205.

In some embodiments, in a layout, the first drain metal D1 is divided into a front-end first drain metal D1 and a rear-end first drain metal D1;

the second drain metal D2 is divided into a front-end second drain metal D2 and a rear-end second drain metal D2;

the front-end first drain metal D1 is located directly above a front end of the drain-side heavily doped region 208 of the left electronic fuse storage unit, and the front-end first drain metal D1 is shorted to the front end of the drain-side heavily doped region 208 of the left electronic fuse storage unit by a vertical contact hole;

the rear-end first drain metal D1 is located directly above a rear end of the drain-side heavily doped region 208 of the left electronic fuse storage unit, and the rear-end first drain metal D1 is shorted to the rear end of the drain-side heavily doped region 208 of the left electronic fuse storage unit by the vertical contact hole;

the front-end second drain metal D2 is located directly above the front end of the drain-side heavily doped region 208 of the right electronic fuse storage unit, and the front-end second drain metal D2 is shorted to the front end of the drain-side heavily doped region 208 of the right electronic fuse storage unit by the vertical contact hole;

the rear-end second drain metal D2 is located directly above the rear end of the drain-side heavily doped region 208 of the right electronic fuse storage unit, and the rear-end second drain metal D2 is shorted to the rear end of the drain-side heavily doped region 208 of the right electronic fuse storage unit by the vertical contact hole;

the first source metal S1 is located directly above a middle portion of the drain-side heavily doped region 208 of the left electronic fuse storage unit, and the first source metal S1 is shorted to the middle portion of the drain-side heavily doped region 208 of the left electronic fuse storage unit by the vertical contact hole;

the second source metal S2 is located directly above a middle portion of the drain-side heavily doped region 208 of the right electronic fuse storage unit, and the second source metal S2 is shorted to the middle portion of the drain-side heavily doped region 208 of the right electronic fuse storage unit by the vertical contact hole;

the word line metal W and bit line metal BL are perpendicular;

the word line metal W, the drain metal D and the source metal S are arranged in parallel;

the front-end first drain metal D1, and the front-end second drain metal D2 have left-right-direction centerlines located on a same straight line and having a left-to-right spacing;

the rear-end first drain metal D1, and the rear-end second drain metal D2 have left-right-direction centerlines located on a same straight line and having a left-to-right spacing;

vertical projections of the second word line metal W2, the front-end first drain metal D1, the first source metal S1, the rear-end first drain metal D1, and the first word line metal W1 are sequentially arranged in parallel from front to back; and

vertical projections of the second word line metal W2, the front-end second drain metal D2, the second source metal S2, the rear-end second drain metal D2, and the first word line metal W1 are sequentially arranged in parallel from front to back.

In the electronic fuse (efuse) storage unit of the present application, the fuse 2 has two states, a conducting state and a fusing state, the fuse 2 is in the conducting state when the efuse storage unit structure is in an initial state, and the fuse 2 is in the fusing state when the efuse storage unit structure is in a programming state. In the electronic fuse storage unit, the control transistor 1 and polycrystalline silicon fuse 2 are formed in a same active area (AA), the elongated-shape polycrystalline silicon fuse 2 is located at a side of the MOS control transistor and has an end shorted to an end of a drain-side heavily doped region 208 of a nearest MOS control transistor, the area of the electronic fuse storage unit is greatly reduced, and it is facilitated to directly perform a combination layout by forming storage unit pairs in a center-symmetric manner to form a storage unit array, and thus the free area in the layout arrangement of the storage array composed by the electric fuse storage unit can be reduced, thereby reducing the layout area of the storage array and obviously increasing the layout efficiency for composing the storage array by the electronic fuse storage unit. In practice, the actual area of the layout design of the electronic fuse storage unit can be reduced to be less than 20% of an area of a layout design of a conventional electronic fuse storage unit. In addition, the elongated-shape polycrystalline silicon is employed as the fuse 2, enabling easy manufacturing and convenient quality controlling, and uniform controllable electronic migration during programming and high reliability after programming is completed.

### BRIEF DESCRIPTION OF THE DRAWINGS

To more clearly illustrate the technical solution of the present application, the figures to be used in the application are briefly introduced below. Obviously, the figures in the description below are only some embodiments of the present application, and according to these figures, other figures can be obtained by those of ordinary skill in the art without the exercise of inventive effort.

FIG. 1 is a schematic diagram of a layout region and a dimension thereof of an existing fuse storage unit of a metal fuse;

FIG. 2 is a schematic diagram of a layout structure of a polysilicon layer according to an embodiment of a fuse storage unit of the present application;

FIG. 3 is a equivalent circuit of the electric fuse storage unit of the present application;

FIG. 4 is a schematic diagram of a layout structure of a polysilicon layer of a storage unit pair according to an embodiment of a storage array composed by a fuse storage unit of the present application;

FIG. 5 is a schematic diagram of a layout structure stacked with a metal layer on the basis of FIG. 4; and

FIG. 6 is an equivalent circuit diagram of the layout structure of the storage unit pair shown in FIG. 5.

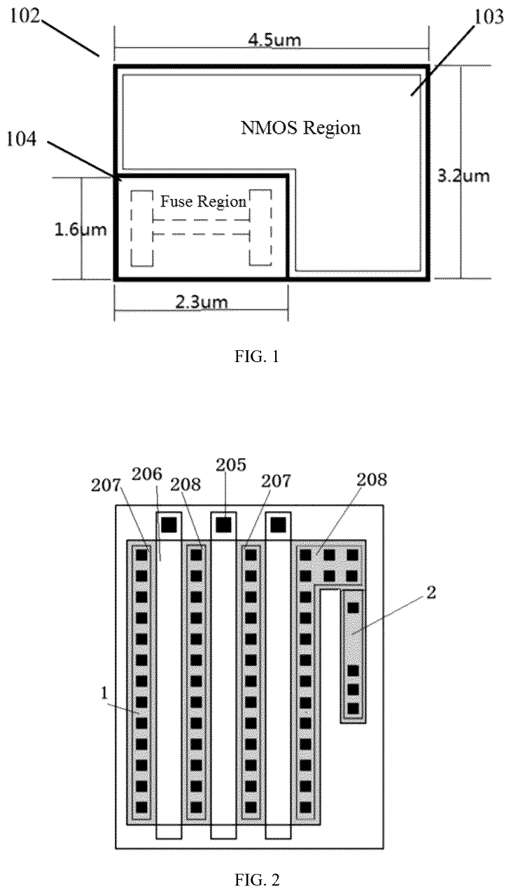

### DESCRIPTION OF REFERENCE NUMBER IN FIGURES

1. control transistor; 2. fuse; 207. source-side heavily doped region; 208. drain-side heavily doped region; 205. contact hole; 206. gate structure; 4. storage unit pair; 41. left electronic fuse storage unit; 42. right electronic fuse storage unit.

### Detailed Description Of The Disclosure

The technical solution in the present application is described clearly below in conjunction with the figures. Obviously, the described embodiments are a part of the embodiments of the present application, not all the embodiments. Based on the embodiments in the present application, all other embodiments obtained by those of ordinary skill in the art without the exercise of inventive effort fall within the scope of protection of the present application.

### Embodiment I

Referring to FIG. 2, an electronic fuse (efuse) storage unit comprises a control transistor 1 consisting of MOS transistors and a fuse 2;

the control transistor 1 and fuse 2 are formed in a same active area (AA);

the fuse 2 is an elongated-shape polycrystalline silicon fuse, and located at an A side of the control transistor 1, A being left or right;

length directions of source-side heavily doped regions 207, and drain-side heavily doped regions 208 of respective MOS transistors of the control transistor 1, and the fuse 2 are all a front-to-rear direction;

front ends and rear ends of the source-side heavily doped regions 207, and the drain-side heavily doped regions 208 of the respective MOS transistors are aligned, respectively;

tops of the source-side heavily doped regions 207 of the respective MOS transistors are shorted to a source metal S formed on a first metal layer S by a contact hole 205;

tops of the drain-side heavily doped regions 208 of the respective MOS transistors are shorted to a drain metal D formed on a second metal layer M2 by the contact holes 205;

gate structures 206 of the respective MOS transistors are shorted to a word line metal W formed on the second metal layer M2 by the contact holes 205; and the fuse 2 has an end shorted to a front end or a rear end of a drain-side heavily doped region 208 of an MOS transistor closest to the A side that constitutes the control transistor 1, and the other end located at an A side of a middle portion in a front-to-rear direction of MOS transistor closest to the A side that constitutes the control transistor 1, and shorted to a bit line metal BL formed at a third metal layer M3 by the contact holes 205.

In the electronic fuse (efuse) storage unit of embodiment I, the fuse 2 has two states, a conducting state and a fusing state, the fuse 2 is in the conducting state when the efuse storage unit structure is in an initial state, and the fuse 2 is in the fusing state when the efuse storage unit structure is in a programming state. In the electronic fuse storage unit, the control transistor 1 and polycrystalline silicon fuse 2 are formed in a same active area (AA), the elongated-shape polycrystalline silicon fuse 2 is located at a side of the MOS control transistor and has an end shorted to an end of a drain-side heavily doped region 208 of a nearest MOS control transistor, the area of the electronic fuse storage unit is greatly reduced, and it is facilitated to directly perform a combination layout by forming storage unit pairs in a center-symmetric manner to form a storage unit array, and thus the free area in the layout arrangement of the storage array composed by the electric fuse storage unit can be reduced, thereby reducing the layout area of the storage array and obviously increasing the layout efficiency for composing the storage array by the electronic fuse storage unit. In practice, the actual area of the layout design of the electronic fuse storage unit can be reduced to be less than 20% of an area of a layout design of a conventional electronic fuse storage unit. In addition, the elongated-shape polycrystalline silicon is employed as the fuse 2, enabling easy manufacturing and convenient quality controlling, and uniform controllable electronic migration during programming and high reliability after programming is completed.

### Embodiment II

Based on the electronic fuse (efuse) storage unit of embodiment I, a front end or a rear end of the drain-side heavily doped region 208 of the MOS transistor closest to the A side that constitutes the control transistor 1 protrudes towards the A side, forming an L-shape; and

an A side of the fuse 2 is aligned with an A side of a protruding portion of the front end or rear end of the drain-side heavily doped region 208 of the MOS transistor closest to the A side that constitutes the control transistor 1.

### Embodiment III

Based on the electronic fuse storage unit of embodiment I, the source-side heavily doped regions 207, and the drain-side heavily doped regions 208 of the respective MOS transistors are formed in a self-aligned mode in active areas of both left and right sides of gate structures 206 of the respective MOS transistors; and the source-side heavily doped regions 207, the drain-side heavily doped regions 208, and the gate structures 206 of the respective MOS transistors are also in an elongated shape in a front-to-rear direction.

Preferably, the gate structures 206 comprise gate dielectric layers and gate polysilicon layers stacked in sequence.

Preferably, for the material of the gate dielectric layers, a high-dielectric-constant material is employed.

Preferably, for the material of the gate dielectric layers, silicon dioxide is employed.

### Embodiment IV

Based on the electronic fuse storage unit of embodiment I, the control transistor 1 is formed by connecting N MOS transistors in parallel, N being an integer greater than 1;

the gate structures 206 of the respective MOS transistors are arranged in an elongated shape in a front-to-rear direction; and

a source-side heavily doped region 207 or a drain-side heavily doped region 208 located between two gate structures 206 is shared by two MOS transistor units adjacent from left to right.

Preferably, N is 2, 3, 4 or 5.

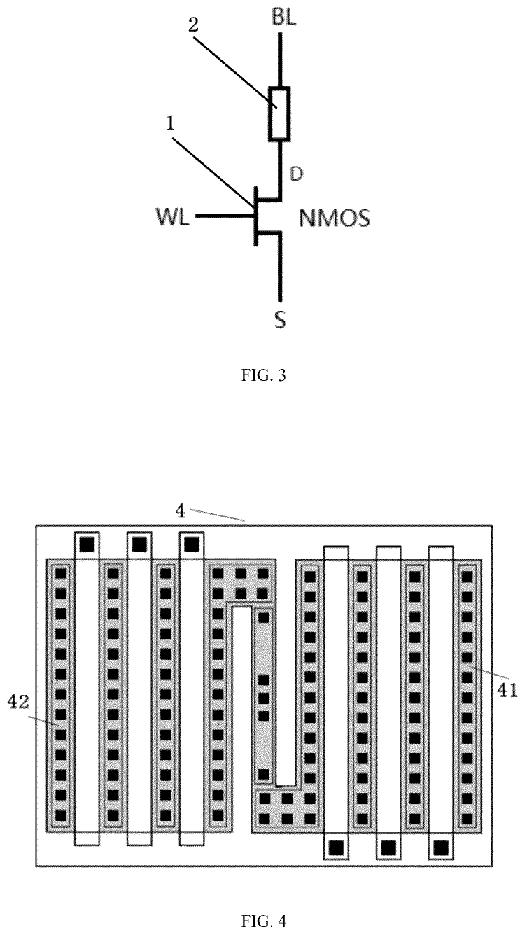

In FIGS. 2, 3 MOS transistors are shown, and one MOS transistor corresponds to one gate structure 206, with 3 gate structures 206 in total. Also, there are two source-side heavily doped regions 207 and two drain-side heavily doped regions 208, which are, from left to right, a source-side heavily doped region 207, a drain-side heavily doped region 208, a source-side heavily doped region 207, and a drain-side heavily doped region 208, respectively; and a front end of a rightmost drain-side heavily doped region 208 is shorted to the front end of the fuse 2, and the rear end of the fuse 2 is located on the right of the middle portion in a front-to-rear direction of the rightmost drain-side heavily doped region 208.

Preferably, the MOS transistor is an NMOS transistor. Referring to FIG. 3, it is an equivalent circuit of the electronic fuse storage unit. The electronic fuse storage unit has 3 electrode ports for connection to external circuits, which are a source port, a word line port and a bit line port, respectively. A drain metal D shorted to tops of drain-side heavily doped regions 208 of respective MOS transistors does not directly form a port for external connection; and if the fuse 2 is in a conducting state, a drain metal D shorted to a top of a drain-side heavily doped regions 208 of an MOS transistor is connected to an external bit line port.

### Embodiment V

An electronic fuse storage array consisting of the electronic fuse storage units of embodiment I to embodiment IV comprises a plurality of storage unit pairs 4;

referring to FIG. 4, each storage unit pair 4 comprises a left electronic fuse storage unit 41 and a right electronic fuse storage unit 42;

a fuse 2 of the left electronic fuse storage unit 41 is located on the left of the control transistor 1, and the fuse 2 has an end shorted to a front end of a drain-side heavily doped region 208 of a leftmost MOS transistor that constitutes the control transistor 1, and the other end located on the left of a middle portion in a front-to-rear direction of the drain-side heavily doped region 208 of the leftmost MOS transistor that constitutes the control transistor 1;

a fuse 2 of the right fuse storage unit 42 is located on the right of the control transistor 1, the fuse 2 has an end shorted to a rear end of a drain-side heavily doped region 208 of a rightmost MOS transistor that constitutes the control transistor 1, and the other end located on the right of a middle portion in a front-to-rear direction of the drain-side heavily doped region 208 of the rightmost MOS transistor that constitutes the control transistor 1; and

the fuse 2 of the left electronic fuse storage unit 41 and the fuse 2 of the right electronic fuse storage unit 42 are connected into a whole in a front-to-rear direction.

The electronic fuse storage array in embodiment V is formed by repeatedly arranging a plurality of storage unit pairs 4, both left and right electronic fuse storage units of the storage unit pair are in central symmetry in the layout, and the fuses 2 of the both left and right electronic fuse storage units in the storage unit pair are connected into a whole in a front-to-rear direction to share a front-to-rear elongated region of an active area, which can effectively reduce a layout area.

### Embodiment VI

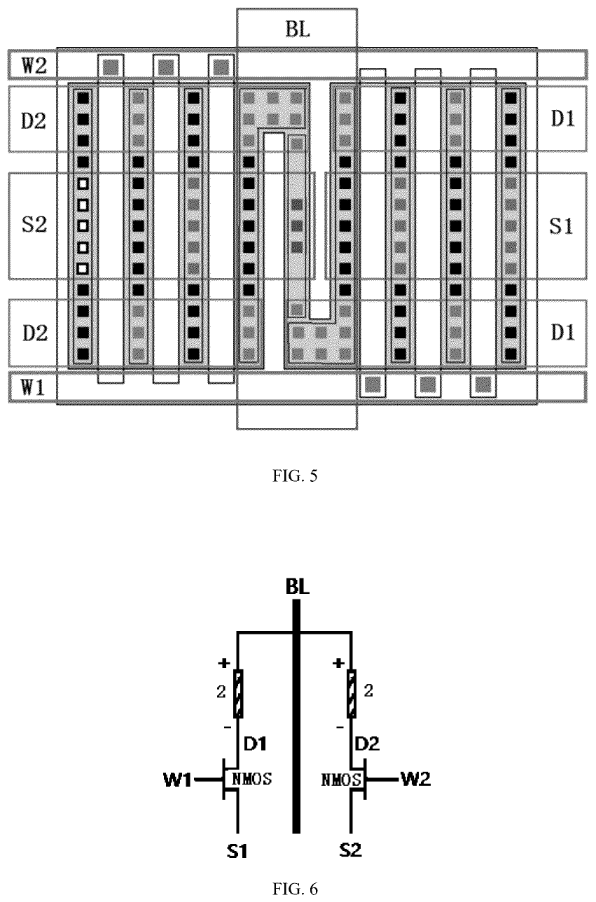

Based on the electronic fuse storage array in embodiment V, referring to FIG. 5 (FIG. 5 is a layout stacked with a metal layer based on FIG. 4), the middle connection area of fuses 2 of both left and right electronic fuse storage units in a storage unit pair are shorted to a bit line metal BL formed on a third metal layer M3 by corresponding contact holes 205;

respective gate structures 206 of the left electronic fuse storage unit are shorted to a first word line metal W1 formed on a second metal layer M2 by corresponding contact holes 205;

respective gate structures 206 of the right electronic fuse storage unit are shorted to a second word line metal W2 formed on the second metal layer M2 by corresponding contact holes 205;

tops of drain-side heavily doped regions 208 of respective MOS transistors of the left electronic fuse storage unit are shorted to a first drain metal D1 formed on the second metal layer M2 by contact holes 205;

tops of drain-side heavily doped regions 208 of respective MOS transistors of the right electronic fuse storage unit are shorted to a second drain metal D2 formed on the second metal layer M2 by contact holes 205;

tops of source-side heavily doped regions 207 of respective MOS transistors of the left electronic fuse storage unit are shorted to a first source metal S1 formed on the first metal layer M1 by contact holes 205; and

tops of source-side heavily doped regions 207 of respective MOS transistors of the right electronic fuse storage unit are shorted to a second source metal S2 formed on the first metal layer M1 by contact holes 205.

Preferably, in a layout, the first drain metal D1 is divided into a front-end first drain metal D1 and a rear-end first drain metal D1;

the second drain metal D2 is divided into a front-end second drain metal D2 and a rear-end second drain metal D2;

the front-end first drain metal D1 is located directly above a front end of the drain-side heavily doped region 208 of the left electronic fuse storage unit, and the front-end first drain metal D1 is shorted to the front end of the drain-side heavily doped region 208 of the left electronic fuse storage unit by a vertical contact hole;

the rear-end first drain metal D1 is located directly above a rear end of the drain-side heavily doped region 208 of the left electronic fuse storage unit, and the rear-end first drain metal D1 is shorted to the rear end of the drain-side heavily doped region 208 of the left electronic fuse storage unit by the vertical contact hole;

the front-end second drain metal D2 is located directly above the front end of the drain-side heavily doped region 208 of the right electronic fuse storage unit, and the front-end second drain metal D2 is shorted to the front end of the drain-side heavily doped region 208 of the right electronic fuse storage unit by the vertical contact hole;

the rear-end second drain metal D2 is located directly above the rear end of the drain-side heavily doped region 208 of the right electronic fuse storage unit, and the rear-end second drain metal D2 is shorted to the rear end of the drain-side heavily doped region 208 of the right electronic fuse storage unit by the vertical contact hole;

the first source metal S1 is located directly above a middle portion of the drain-side heavily doped region 208 of the left electronic fuse storage unit, and the first source metal S1 is shorted to the middle portion of the drain-side heavily doped region 208 of the left electronic fuse storage unit by the vertical contact hole;

the second source metal S2 is located directly above a middle portion of the drain-side heavily doped region 208 of the right electronic fuse storage unit, and the second source metal S2 is shorted to the middle portion of the drain-side heavily doped region 208 of the right electronic fuse storage unit by the vertical contact hole;

the word line metal W and bit line metal BL are perpendicular;

the word line metal W, the drain metal D and the source metal S are arranged in parallel;

the front-end first drain metal D1, and the front-end second drain metal D2 have left-right-direction centerlines located on a same straight line and having a left-to-right spacing;

the rear-end first drain metal D1, and the rear-end second drain metal D2 have left-right-direction centerlines located on a same straight line and having a left-to-right spacing;

vertical projections of the second word line metal W2, the front-end first drain metal D1, the first source metal S1, the rear-end first drain metal D1, and the first word line metal W1 are sequentially arranged in parallel from front to back; and

vertical projections of the second word line metal W2, the front-end second drain metal D2, the second source metal S2, the rear-end second drain metal D2, and the first word line metal W1 are sequentially arranged in parallel from front to back.

The equivalent circuit of the storage unit pair shown in FIG. 5 is shown in FIG. 6.

Only preferred embodiments of the present application are described above and are not intended to limit the present application. Any modifications, equivalent replacements, improvements, etc. made within the spirit and principle of the present application shall be included within the scope of protection of the present application.

What is claimed is:

1. An electronic fuse storage unit, wherein the electronic fuse storage unit comprises a control transistor (1) consisting of MOS transistors, and a fuse (2);
the control transistor and fuse (2) are formed in a same active area;
the fuse (2) is an elongated-shape polycrystalline silicon fuse, and located at an A side of the control transistor (1), A being left or right;
length directions of source-side heavily doped regions (207), and drain-side heavily doped regions (208) of respective MOS transistors of the control transistor (1), and the fuse (2) are all a front-to-rear direction;
front ends and rear ends of the source-side heavily doped regions (207), and the drain-side heavily doped regions (208) of the respective MOS transistors of the control transistor (1) are aligned, respectively;
tops of the source-side heavily doped regions (207) of the respective MOS transistors are shorted to a source metal formed on a first metal layer by a contact hole (205);
tops of the drain-side heavily doped regions (208) of the respective MOS transistors are shorted to a drain metal formed on a second metal layer by the contact holes (205);
gate structures (206) of the respective MOS transistors are shorted to a word line metal formed on the second metal layer by the contact holes (205); and
the fuse (2) has an end shorted to a front end or a rear end of a drain-side heavily doped region (208) of an MOS transistor closest to the A side that constitutes the control transistor

(1) and the other end located at an A side of a middle portion in a front-to-rear direction of MOS transistor closest to the A side that constitutes the control transistor (1), and shorted to a bit line metal formed at a third metal layer by the contact holes (205).

2. The electronic fuse storage unit according to claim 1, wherein
a front end or a rear end of the drain-side heavily doped region (208) of the MOS transistor closest to the A side that constitutes the control transistor (1) protrudes towards the A side, forming an L-shape; and
an A side of the fuse (2) is aligned with an A side of a protruding portion of the front end or rear end of the drain-side heavily doped region (208) of the MOS transistor closest to the A side that constitutes the control transistor (1).

3. The electronic fuse storage unit according to claim 1, wherein
the source-side heavily doped regions (207), and the drain-side heavily doped regions (208) of the respective MOS transistors are formed in a self-aligned mode in active areas of both left and right sides of gate structures (206) of the respective MOS transistors; and
the source-side heavily doped regions (207), the drain-side heavily doped regions (208), and the gate structures (206) of the respective MOS transistors are also in an elongated shape in a front-to-rear direction.

4. The electronic fuse storage unit according to claim 1, wherein the gate structures (206) comprise gate dielectric layers and gate polysilicon layers stacked in sequence; and
for the material of the gate dielectric layers, a high-dielectric-constant material or silicon dioxide is employed.

5. The electronic fuse storage unit according to claim 1, wherein
the control transistor (1) is formed by connecting N MOS transistors in parallel, N being an integer greater than 1;
the gate structures (206) of the respective MOS transistors are arranged in an elongated shape in a front-to-rear direction; and
a source-side heavily doped region (207) or a drain-side heavily doped region (208) located between two gate structures (206) is shared by two MOS transistor units adjacent from left to right.

6. The electronic fuse storage unit according to claim 5, wherein N is 2, 3, 4 or 5.

7. The electronic fuse storage unit according to claim 1, wherein the MOS transistor is an NMOS transistor.

8. An electronic fuse storage array composed by the electronic fuse storage unit according to claim 1, wherein the electronic fuse storage array comprises a plurality of storage unit pairs (4);
each storage unit pair (4) comprises a left electronic fuse storage unit (41) and a right electronic fuse storage unit (42);
a fuse (2) of the left electronic fuse storage unit (41) is located on the left of the control transistor (1), and the fuse (2) has an end shorted to a front end of a drain-side heavily doped region (208) of a leftmost MOS transistor that constitutes the control transistor (1), and the other end located on the left of a middle portion in a front-to-rear direction of the drain-side heavily doped region (208) of the leftmost MOS transistor that constitutes the control transistor (1);
a fuse (2) of the right fuse storage unit (42) is located on the right of the control transistor (1), and the fuse (2) has an end shorted to a rear end of a drain-side heavily doped region (208) of a rightmost MOS transistor that constitutes the control transistor (1), and the other end located on the right of a middle portion in a front-to-rear direction of the drain-side heavily doped region (208) of the rightmost MOS transistor that constitutes the control transistor (1); and
the fuse (2) of the left electronic fuse storage unit (41) and the fuse (2) of the right electronic fuse storage unit (42) are connected into a whole in a front-to-rear direction.

9. The electronic fuse storage array according to claim 8, wherein a middle connection area of fuses (2) of both left and right electronic fuse storage units in the storage unit pair are shorted to a bit line metal formed on a third metal layer by corresponding contact holes (205);
respective gate structures (206) of the left electronic fuse storage unit are shorted to a first word line metal formed on a second metal layer by corresponding contact holes (205);
respective gate structures (206) of the right electronic fuse storage unit are shorted to a second word line metal formed on the second metal layer by corresponding contact holes (205);
tops of drain-side heavily doped regions (208) of respective MOS transistors of the left electronic fuse storage unit are shorted to a first drain metal formed on the second metal layer by contact holes (205);
tops of drain-side heavily doped regions (208) of respective MOS transistors of the right electronic fuse storage unit are shorted to a second drain metal formed on the second metal layer by contact holes (205);
tops of source-side heavily doped regions (207) of the respective MOS transistors of the left electronic fuse storage unit are shorted to a first source metal formed on a first metal layer by contact holes (205); and
tops of source-side heavily doped regions (207) of the respective MOS transistors of the right electronic fuse storage unit are shorted to a second source metal formed on the first metal layer by contact holes (205).

10. The electronic fuse storage array according to claim 9, wherein
in a layout, the first drain metal is divided into a front-end first drain metal and a rear-end first drain metal;
the second drain metal is divided into a front-end second drain metal and a rear-end second drain metal;
the front-end first drain metal is located directly above a front end of the drain-side heavily doped region (208) of the left electronic fuse storage unit, and the front-end first drain metal is shorted to the front end of the drain-side heavily doped region (208) of the left electronic fuse storage unit by a vertical contact hole;
the rear-end first drain metal is located directly above a rear end of the drain-side heavily doped region (208) of the left electronic fuse storage unit, and the rear-end first drain metal is shorted to the rear end of the drain-side heavily doped region (208) of the left electronic fuse storage unit by the vertical contact hole;
the front-end second drain metal is located directly above the front end of the drain-side heavily doped region (208) of the right electronic fuse storage unit, and the front-end second drain metal is shorted to the front end of the drain-side heavily doped region (208) of the right electronic fuse storage unit by the vertical contact hole;
the rear-end second drain metal is located directly above the rear end of the drain-side heavily doped region (208) of the right electronic fuse storage unit, and the rear-end second drain metal is shorted to the rear end of the drain-side heavily doped region (208) of the right electronic fuse storage unit by the vertical contact hole;
the first source metal is located directly above a middle portion of the drain-side heavily doped region (208) of the left electronic fuse storage unit, and the first source metal is shorted to the middle portion of the drain-side heavily doped region (208) of the left electronic fuse storage unit by the vertical contact hole;
the second source metal is located directly above a middle portion of the drain-side heavily doped region (208) of the right electronic fuse storage unit, and the second source metal is shorted to the middle portion of the drain-side heavily doped region (208) of the right electronic fuse storage unit by the vertical contact hole;
the word line metal and bit line metal are perpendicular;
the word line metal, the drain metal and the source metal are arranged in parallel;
the front-end first drain metal, and the front-end second drain metal have left-right-direction centerlines located on a same straight line and having a left-to-right spacing;
the rear-end first drain metal, and the rear-end second drain metal have left-right-direction centerlines located on a same straight line and having a left-to-right spacing;
vertical projections of the second word line metal, the front-end first drain metal, the first source metal, the rear-end first drain metal, and the first word line metal are sequentially arranged in parallel from front to back; and
vertical projections of the second word line metal, the front-end second drain metal, the second source metal, the rear-end second drain metal, and the first word line metal are sequentially arranged in parallel from front to back.
